(19) United States
(12) Patent Application Publication
(10) Pub. No.: US 2026/0110710 A1
(43) Pub. Date: Apr. 23, 2026

(54) Method and System for Determining the Structural Integrity of Materials

(71) Applicant: The United States of America as Represented by the Secretary of Agriculture, Washington, DC (US)

(72) Inventor: Christopher Senalik, DeForest, WI (US)

(21) Appl. No.: 18/924,124

(22) Filed: Oct. 23, 2024

(51) Int. Cl. G01R 1/067

(52) U.S. Cl. CPC G01R 1/06722

(57) ABSTRACT

A probe holder device includes an outer tube. The outer tube includes a distal end and a proximal end, and the proximal end is at least partially covered by a cover. The probe holder device also includes a carriage that includes an upper carriage, a lower carriage, and one or springs that extend between the upper carriage and the lower carriage. The probe holder device further includes a compression stop that mounts to the distal end of the outer tube. The compression stop includes an opening.

### BACKGROUND

Maintaining the structural integrity of buildings, bridges, and other manmade structures is important to help avoid safety hazards and possible catastrophes that result from structural failure. For example, a bridge that spans a river may be made from a combination of wood, metal, and concrete products. Similarly, buildings (anywhere from residential homes to skyscrapers) can be made from a variety of different materials. Depending on a number of different factors (e.g., climate, initial condition/quality of the building materials, wear and tear, etc.), the various materials used to construct a structure can deteriorate at different rates, and this deterioration may not be ascertainable from a visible inspection of the structure. It is therefore necessary to occasionally inspect structures in an effort to identify deterioration in advance of a structural failure.

### SUMMARY

An illustrative probe holder device includes an outer tube. The outer tube includes a distal end and a proximal end, and the proximal end is at least partially covered by a cover. The probe holder device also includes a carriage that includes an upper carriage, a lower carriage, and one or springs that extend between the upper carriage and the lower carriage. The probe holder device further includes a compression stop that mounts to the distal end of the outer tube. The compression stop includes an opening.

In an illustrative embodiment, the opening in the compression stop is sized to receive at least a portion of a probe mounted within the outer tube such that at least the portion of the probe extends past the distal end of the outer tube. In another embodiment, the compression stop includes a plurality of posts that extend into the outer tube, and the plurality of posts are spaced apart to support at least a portion of a probe that is mounted within the outer tube. In one embodiment, the cover of the proximal end of the outer tube includes an opening that is sized to receive an electrical cord of a probe that is mounted within the outer tube.

In another embodiment, the upper carriage includes a first base with a first plurality of posts extending therefrom, and the one or springs comprise a plurality of springs such that each spring is partially received by a post in the first plurality of posts. Additionally, each post in the first plurality of posts has a different length. In another embodiment, the lower carriage includes a second base with a second plurality of posts extending therefrom, where each spring is partially received by a post in the second plurality of posts, and where each post in the second plurality of posts has a different length. In such an embodiment, a first spring in the plurality of springs mounts to a first set of posts that includes a first post from the first plurality of posts and a first post from the second plurality of posts such that, in an uncompressed state, the mounted first spring causes a first gap to be formed between the first set of posts. Additionally, a second spring in the plurality of springs mounts to a second set of posts that includes a second post from the first plurality of posts and a second post from the second plurality of posts such that, in an uncompressed state, the mounted second spring causes a second gap to be formed between the second set of posts. The first gap begins at a first distance from a distal end of the lower carriage and the second gap begins at a second distance from the distal end of the lower carriage, where the first distance differs from the second distance.

In another embodiment, the probe holder device includes a spacer that mounts within the outer tube such that a proximal end of the spacer is in contact with the cover of the outer tube. In an illustrative embodiment, the length of the spacer controls a distance by which a probe extends from the distal end of the outer tube. In another embodiment, an interior of the spacer includes a truncated cone shape that is sized to at least partially mate with a proximal end of the upper carriage. In one embodiment, an interior surface of a distal end of the lower carriage is sized to at least partially mate with a proximal end of a probe that is mounted within the outer tube. In another embodiment, the upper carriage and the lower carriage each include an opening that is sized to receive an electrical cord of a probe that is mounted within the outer tube. In another embodiment, the probe holder device includes one or more collars mounted to an exterior surface of the outer tube, where the one or more collars are shaped to prevent movement of the outer tube when the outer tube is placed onto a surface.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 depicts an exploded view of a probe holder device for use in determining structural integrity of a material in accordance with an illustrative embodiment.

FIG. 2A is a distal end view depicting an interior of the outer tube in accordance with an illustrative embodiment.

FIG. 2B is a perspective view depicting a proximal end of the outer tube in accordance with an illustrative embodiment.

FIG. 2C is a side view of the outer tube showing collars mounted to an outer surface of the outer tube in accordance with an illustrative embodiment.

FIG. 3A is a top view of the spacer of the probe holder device in accordance with an illustrative embodiment.

FIG. 3B is a perspective bottom view of the spacer of the probe holder device in accordance with an illustrative embodiment.

FIG. 4A is a bottom view of the upper carriage in accordance with an illustrative embodiment.

FIG. 4B is a perspective top view of the upper carriage in accordance with an illustrative embodiment.

FIG. 4C is a perspective bottom view of the upper carriage in accordance with an illustrative embodiment.

FIG. 5A is a top view of the lower carriage in accordance with an illustrative embodiment.

FIG. 5B is a side view of the lower carriage in accordance with an illustrative embodiment.

FIG. 5C is a bottom perspective view of the lower carriage in accordance with an illustrative embodiment.

FIG. 6A is a top perspective view of a spring for use in the probe holder device in accordance with an illustrative embodiment.

FIG. 6B is a side view of the spring for use in the probe holder device in accordance with an illustrative embodiment.

FIG. 7A is a top view of the compression stop of the probe holder device in accordance with an illustrative embodiment.

FIG. 7B is a bottom view of the compression stop in accordance with an illustrative embodiment.

FIG. 7C is a side perspective view of the compression stop in accordance with an illustrative embodiment.

FIG. 8A depicts a partially assembled carriage for the probe holder device in which a first set of posts (without a mounted spring) has a first gap located at a first position in accordance with an illustrative embodiment.

FIG. 8B depicts a partially assembled carriage for the probe holder device in which a second set of posts (without a mounted spring) has a second gap located at a second position (that differs from the first position of the first gap in FIG. 8A) in accordance with an illustrative embodiment.

FIG. 8C depicts a partially assembled carriage for the probe holder device in which a third set of posts (without a mounted spring) has a third gap located at a third position (that differs from both the first position of the first gap in FIG. 8A and the second position of the second gap in FIG. 8B) in accordance with an illustrative embodiment.

FIG. 8D depicts a fully assembled carriage in accordance with an illustrative embodiment.

FIG. 9A is an exploded view of a probe holder device and probe in accordance with an illustrative embodiment.

FIG. 9B depicts a partially assembled probe holder device with a mounted probe in accordance with an illustrative embodiment.

FIG. 9C is an end view of a distal end of the fully assembled probe holder device with a mounted probe in accordance with an illustrative embodiment.

FIG. 9D is an end view of a proximal end of the fully assembled probe holder device with a mounted probe in accordance with an illustrative embodiment.

FIG. 10A is a sectional view that depicts an initial position of the tip of the probe upon contact with a surface that is to be tested in accordance with an illustrative embodiment.

FIG. 10B is a sectional view that depicts a test position of the device in which both the distal end of the outer tube and the tip of the probe are in contact with the surface to be tested in accordance with an illustrative embodiment.

### DETAILED DESCRIPTION

Given the age and condition of many structures (e.g., bridges, buildings, railroad tracks, roads, etc.) in the United States and around the world, structural strength and condition of the materials used to construct these structures are becoming ever more important considerations. Traditional systems for performing field inspections to determine structural integrity of a material generally utilize probes that transmit a wave/signal through the material. Specifically, the probe is placed upon a surface of interest and a signal is transmitted through the material to identify characteristics that relate to its integrity. However, due to a lack of consistency in the amount of pressure used to place the probe into contact with the surface being measured, traditional systems lack repeatability of the measurements. For example, in many traditional devices, the application force applied by the user to place the device against the material being tested greatly affects the device output, and this application force is highly variable, even for the same user. This can result in inconsistent measurements that do not reflect the actual integrity of the material being measured.

With the ever increasing number of structures made from wood, metal, and/or concrete, along with the need for better inspections of aging structures to detect fatigue and wear, it is critical to maintain the correct pressure between the tip of the measurement probe and the material being tested such that the pressure is consistent and repeatable. As discussed, traditional probes are often hand operated with no way for the user to precisely control the pressure with which the probe contacts a measurement surface. Described herein is a spring controlled measurement apparatus that holds a probe against a measurement surface under consistent and repeatable pressure to provide consistent measurement results. Examples are provided of a probe holder device that is sized for a specific probe. In alternative embodiment, the sizes of the various components used to form the probe holder device can be varied to accommodate different sizes and/or types of probes.

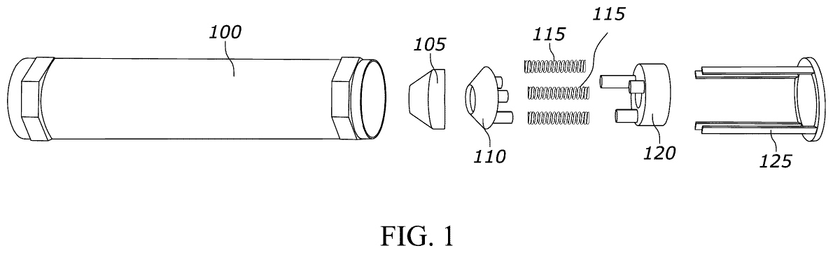

FIG. 1 depicts an exploded view of a probe holder device for use in determining structural integrity of a material in accordance with an illustrative embodiment. The probe holder device acts as a constant pressure housing that enables consistent and repeatable use of a probe/sensor to determine structural integrity of a material. As shown, the device includes an outer tube 100, a spacer 105, an upper carriage 110, springs 115, a lower carriage 120, and a compression stop 125. Each of these components is described in more detail below. In alternative embodiments, the probe holder device can include fewer, additional, and/or different components.

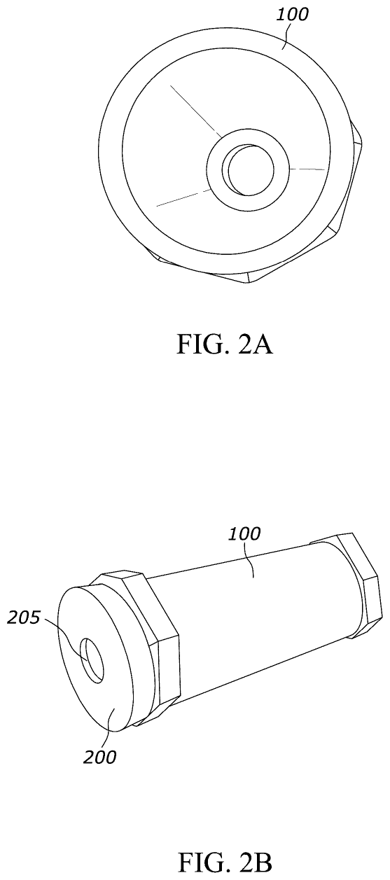

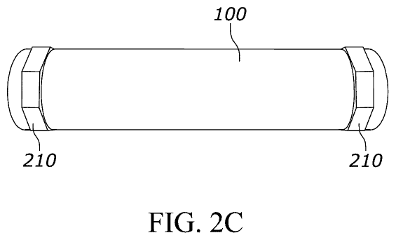

FIG. 2 includes various views of the outer tube 100. Specifically, FIG. 2A is a distal end view depicting an interior of the outer tube in accordance with an illustrative embodiment. As used herein, the “distal end” of the outer tube (or device) refers to the end of the outer tube that is closest to the surface being tested by the device. The “proximal end” of the outer tube (or device) refers to the end of the outer tube that is farthest from the surface being tested (i.e., the end that is closest to the user). As shown, an interior of the outer tube 100 is smooth, and the distal end of the outer tube is open (i.e., not covered).

FIG. 2B is a perspective view depicting a proximal end of the outer tube in accordance with an illustrative embodiment. As shown, the proximal end is capped by a cover 200 that includes an opening 205. The opening 205 is in the center of the cover 200 in the embodiment shown. As shown, the opening 205 is circular in the embodiment of FIG. 2. In alternative embodiments, the opening 205 can be a different shape other than circular (e.g., square, triangle, rectangle, etc.) and/or the opening can be off-center in the cover 200. In an illustrative embodiment, the opening 205 in the cover 200 receives an electrical cord for a probe that mounts within the outer tube. In an alternative embodiment, the probe may be battery operated such that the cover does not include an opening therein.

FIG. 2C is a side view of the outer tube showing collars mounted to an outer surface of the outer tube in accordance with an illustrative embodiment. In the embodiment shown, there are two collars 210 mounted to the outer tube. The collars 210 are utilized to prevent the outer tube from rolling when the device is placed onto a surface. The collars can also act as handles for holding the device during use. The depicted collars 210 are octagonal in shape. In alternative embodiments, the collars can be a different shape such as square, pentagonal, hexagonal, etc. In another alternative embodiment, fewer or additional collars may be used. In another alternative embodiment, collars may not be used. In one such embodiment, an entire outer surface of the outer tube can be shaped or contoured to prevent rolling of the device when placed on a surface.

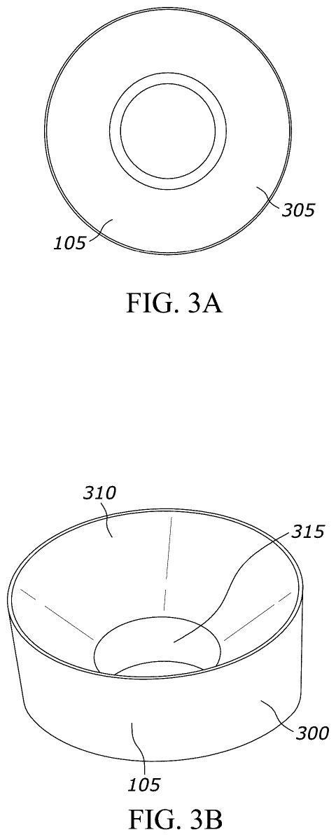

FIG. 3A is a top view of the spacer 105 of the probe holder device in accordance with an illustrative embodiment. FIG. 3B is a perspective bottom view of the spacer 105 of the probe holder device in accordance with an illustrative embodiment. The spacer 105 is used to adjust how much of the probe/sensor extends beyond the end of the tube. As shown, an exterior surface of the spacer 105 includes a cylindrical portion 300 and a truncated cone portion 305 that is connected to the cylindrical portion 300. An interior surface of the cylindrical portion 300 of the spacer 105 is in the form of a truncated cone 310. An interior surface of the truncated cone portion 305 of the spacer 105 includes a cylindrical opening 315. In an illustrative embodiment, when the probe holder device is assembled, the truncated cone portion 305 of the spacer 105 contacts an interior surface of the cover 200 that caps the proximal end of the outer tube 100. The cover 200, in combination with the spacer 105, acts as a hard stop that controls a position of the probe tip relative to the distal end of the outer tube 100. For shorter sensors, a longer spacer can be used and for longer sensors, a shorter spacer can be used. In some embodiments with longer sensors, the spacer can be removed completely and not used.

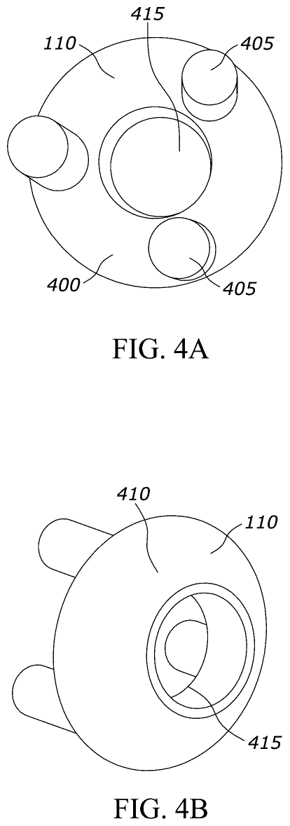

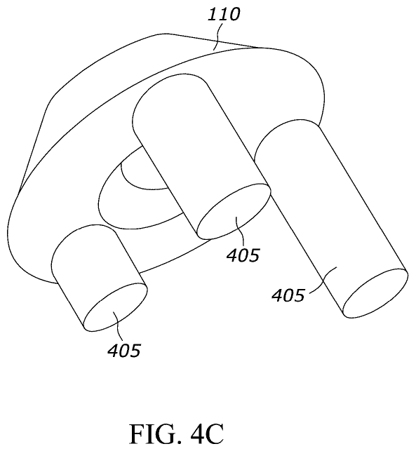

FIG. 4A is a bottom view of the upper carriage 110 in accordance with an illustrative embodiment. FIG. 4B is a perspective top view of the upper carriage 110 in accordance with an illustrative embodiment. FIG. 4C is a perspective bottom view of the upper carriage 110 in accordance with an illustrative embodiment. The upper carriage 110 includes a base portion 400 and posts (or legs) 405 mounted to and extending from the base portion 400. The base portion 400 of the upper carriage 110 has an exterior in the form of a truncated cone 410. The base portion 400 also includes an opening 415 formed therein. The opening 415 is circular in the embodiment shown, but a different shape of opening can be used in alternative embodiments. In an illustrative embodiment, the slope of the truncated cone 410 that forms the exterior surface of the base portion 400 of the upper carriage 110 matches a slope of the truncated cone 310 that forms the interior surface of the cylindrical portion 300 of the spacer 105. These matching slopes mate with one another to ensure that the carriage seats correctly each time during compression of the device. In another illustrative embodiment, the diameter of the upper carriage 110 can match (or be slightly smaller than) an interior diameter of the outer tube 100.

In the embodiment shown, the upper carriage 110 has three posts 405. In alternative embodiments, a different number of posts 405 may be used, such as one, two, four, etc. The posts 405 are used to keep the springs 115 in line during compression and use of the device. In another illustrative embodiment, each of the posts has a different length so that the breaks between the posts 405 of the upper carriage 110 and the posts of the lower carriage 120 do not occur at the same location. In other words, the breaks between each set of posts do not align with one another, where a set of posts includes one post 405 from the upper carriage 110 and one post from the lower carriage 120. Alignment of the sets of posts can potentially cause undesirable bending in the springs 115.

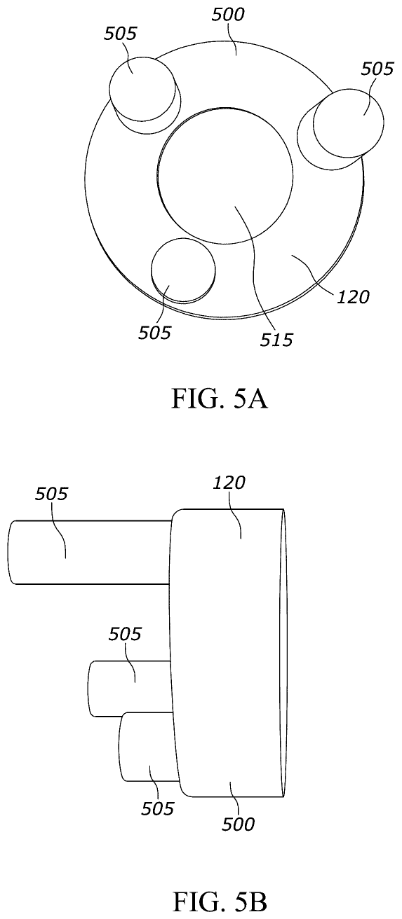

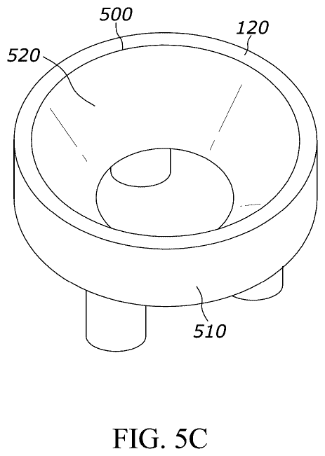

FIG. 5A is a top view of the lower carriage 120 in accordance with an illustrative embodiment. FIG. 5B is a side view of the lower carriage 120 in accordance with an illustrative embodiment. FIG. 5C is a bottom perspective view of the lower carriage 120 in accordance with an illustrative embodiment. The lower carriage 120 includes a base portion 500 and posts (or legs) 505 mounted to and extending from the base portion 500. The base portion 500 of the lower carriage 120 has an exterior in the form of a cylinder 510. The base portion 500 also includes an opening 515 formed therein. The opening 515 is circular in the embodiment shown, but a different shape of opening can be used in alternative embodiments. In an illustrative embodiment, the cylinder 510 that forms the exterior surface of the base portion 500 of the lower carriage 120 is sized to slidably fit within the interior of the outer tube 100. An interior surface of the base portion 500 of the lower carriage 120 has the shape of a truncated cone 520. In an illustrative embodiment, the slope of the truncated cone 520 that forms the interior surface of the base portion 500 lower carriage matches the slope of a top portion of the sensor being used with the device. The matching slopes ensure that the sensor seats correctly in the carriage during compression and use of the device.

In the embodiment shown, the lower carriage 120 has three posts 505. In alternative embodiments, a different number of posts 505 may be used, such as one, two, four, etc. Similar to the posts 405 of the upper carriage 110, the posts 505 of the lower carriage 120 are used to keep the springs 115 in line during compression and use of the device. In another illustrative embodiment, each of the posts 505 has a different length so that the breaks between the posts 405 of the upper carriage 110 and the posts 505 of the lower carriage 120 do not occur at the same location. As a result, the breaks between each set of posts do not align with one another. As discussed, alignment of the sets of posts can potentially cause undesirable bending in the springs 115.

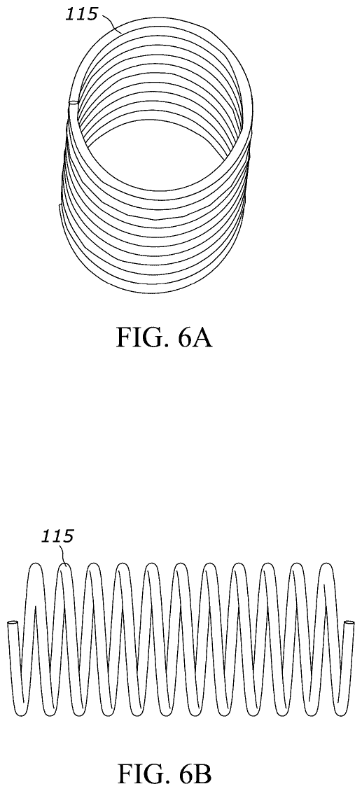

FIG. 6A is a top perspective view of a spring 115 for use in the probe holder device in accordance with an illustrative embodiment. FIG. 6B is a side view of the spring 115 for use in the probe holder device in accordance with an illustrative embodiment. In an illustrative embodiment, three springs are used in the device to provide constant pressure during compression. In alternative embodiments, a different number of springs may be used, such as one, two, four, etc. In such an embodiment, the upper carriage 110 and the lower carriage 120 can be modified to have fewer or additional posts to accommodate the different number of springs. In an embodiment in which a single spring is used, an outer diameter of the single spring can be sized to be approximately (e.g., within 5%) the size of the inner diameter of the outer tube 100. In another illustrative embodiment, commercially available springs can be used in the device.

The overall force needed to properly use the probe holder device can be controlled by the number of springs used in the device and/or by the strength/force (i.e., stiffness constant) of the spring(s) that are used. The force applied by the springs is governed by the compression of the springs, and the compression distance is governed in part by the sets of posts that run through the center of the springs. In one embodiment, when a desired compression distance is achieved, gaps between the posts are closed, which causes the posts from the upper and lower carriage to contact one another, thereby stopping additional compression motion. Because the compression distance is the same, the application force from the springs is the same each time. As discussed, the post lengths can be changed to increase or decrease the compression distance, allowing the user to customize the desired force. Additionally, to increase the force needed to operate the device, additional springs can be used and/or springs with increased stiffness/strength can be used. Similarly, to decrease the force needed to operate the device, fewer springs can be used and/or springs with decreased stiffness/strength can be used.

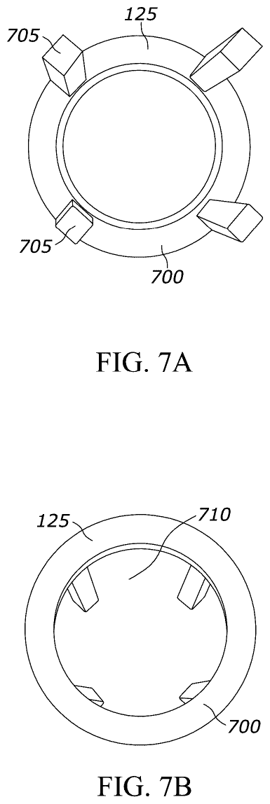

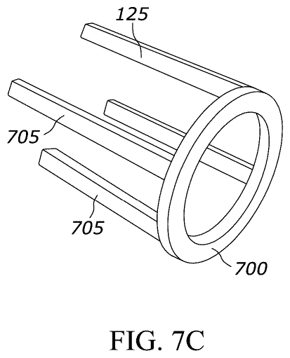

FIG. 7A is a top view of the compression stop 125 of the probe holder device in accordance with an illustrative embodiment. FIG. 7B is a bottom view of the compression stop 125 in accordance with an illustrative embodiment. FIG. 7C is a side perspective view of the compression stop 125 in accordance with an illustrative embodiment. The compression stop 125 includes a base 700 and posts 705 (or legs) that extend from the base 700. In the embodiment shown, there are four posts 705 that extend from the base 700. In alternative embodiments, additional or fewer posts 705 may be used, such as two, three, five, etc. The posts 705 are arranged to position the sensor, to hold the sensor in place, and to prevent excessive movement of the sensor once it is mounted within the outer tube 100. The compression stop 125 also includes an opening 710 in the base 700. The opening 710 allows at least a portion of a probe (e.g., the probe tip) mounted within the outer tube to extend past the distal end of the outer tube. This configuration is described in more detail below.

In an illustrative embodiment, the compression stop 125 is sized to fit into the distal end of the outer tube 100 to hold the sensor in place and to prevent the sensor from falling out of the outer tube 100. In one embodiment, the compression stop 125 is held in place by a friction fit. Alternatively, the compression stop 125 can be held in place by threads included on the compression stop 125 that mate with threads formed in the interior surface of the outer tube 100. Alternatively, in an embodiment in which the proximal end of the outer tube 100 is open, the compression stop 125 can be permanently mounted to the distal end of the outer tube via co-molding, adhesive, etc.

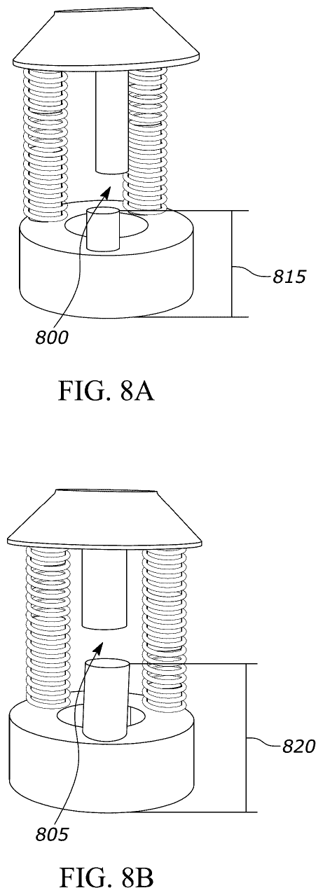

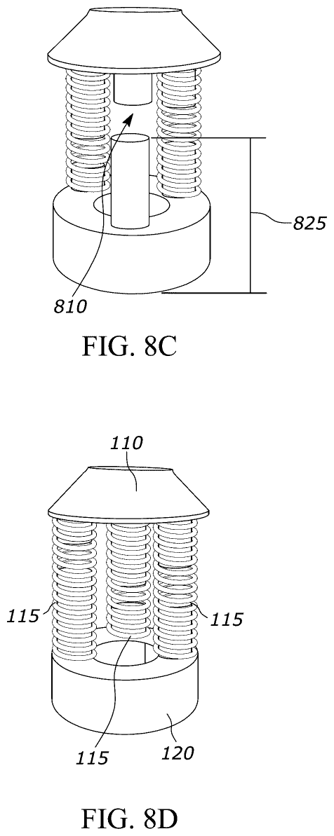

FIG. 8A depicts a partially assembled carriage for the probe holder device in which a first set of posts (without a mounted spring) has a first gap 800 located at a first position in accordance with an illustrative embodiment. FIG. 8B depicts a partially assembled carriage for the probe holder device in which a second set of posts (without a mounted spring) has a second gap 805 located at a second position (that differs from the first position of the first gap in FIG. 8A) in accordance with an illustrative embodiment. FIG. 8C depicts a partially assembled carriage for the probe holder device in which a third set of posts (without a mounted spring) has a third gap 810 located at a third position (that differs from both the first position of the first gap in FIG. 8A and the second position of the second gap in FIG. 8B) in accordance with an illustrative embodiment. As such, the three gaps are not aligned with one another along a length of the assembled carriage (i.e., along a length of the outer tube 100 when the assembled carriage is positioned within the outer tube 100).

Specifically, as shown in FIGS. 8A-8C, the first gap 800 starts at a first distance 815 from a distal end of the lower carriage 120. The second gap 805 starts at a second distance 820 from a distal end of the lower carriage 120, where the second distance 820 is greater than the first distance 815. The third gap starts at a third distance 825 from the distal end of the lower carriage 120, wherein the third distance 825 is greater than both the first distance 815 and the second distance 820. In an illustrative embodiment, the length of each of the gaps is the same such that compression of the springs 115 results in simultaneous contact of the three posts mounted to the upper carriage 110 with the three posts mounted to the lower carriage 120. FIG. 8D depicts a fully assembled carriage in accordance with an illustrative embodiment.

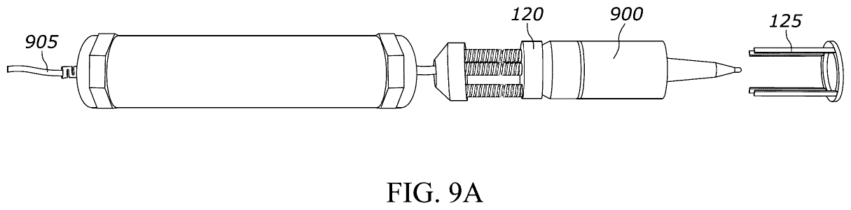

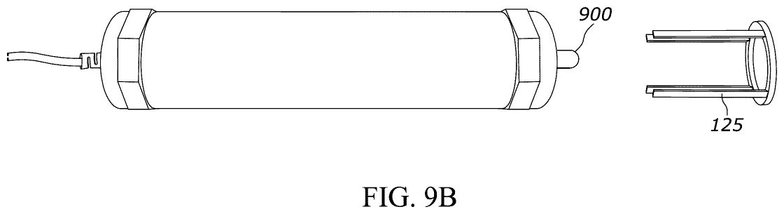

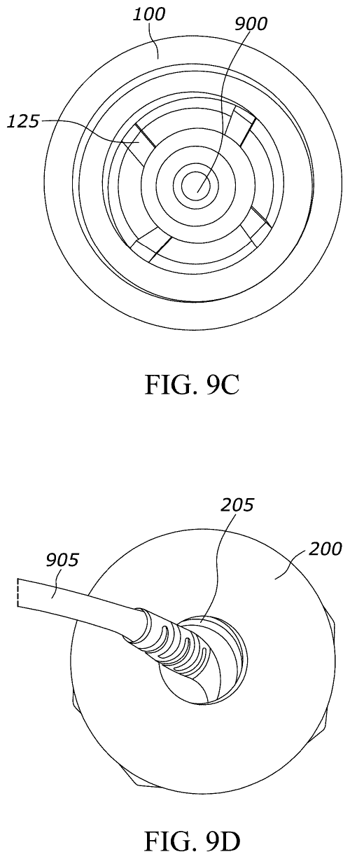

FIG. 9A is an exploded view of a probe holder device and probe 900 in accordance with an illustrative embodiment. FIG. 9B depicts a partially assembled probe holder device with a mounted probe 900 in accordance with an illustrative embodiment. FIG. 9C is an end view of a distal end of the fully assembled probe holder device with a mounted probe in accordance with an illustrative embodiment. FIG. 9D is an end view of a proximal end of the fully assembled probe holder device with a mounted probe in accordance with an illustrative embodiment. As shown, an electrical cord 905 is connected to a proximal end of the probe 900 and used to provide power to the probe 900. The electrical cord 905 extends through the openings in the assembled carriage and through the opening 205 in the cover 200 (or end cap) at the proximal end of the outer tube. In an alternative embodiment, the probe 900 may be battery powered such that the electrical cord 905 and/or the openings that allow the electrical cord to pass through the device may not be included. As shown in FIG. 9A, the proximal end of the probe 900 is tapered to mate with the truncated cone formed on the interior surface of the lower carriage 120.

As depicted in FIG. 9B and FIG. 9C, a portion of a tip of the probe 900 extends from the end of the probe holder device when the probe 900 is mounted therein. During use of the device, this tip of the probe 900 is placed into contact with a surface for measurement of the integrity of the structural component that includes the surface. Specifically, upon contact of the probe tip with the surface of interest, the user can continue to apply pressure to the probe holder device, which causes the probe to partially recess into the probe holder device as a result of compression of the springs. The probe is recessed until the distal end of the outer tube is in contact with the surface of interest. As a result of the springs and the placement of the probe holder device (i.e., with the distal end thereof in contact with the surface), the probe presses against the surface with a known pressure that is repeatable every time the device is used in this manner. As a result, measurements taken by the probe (mounted within the probe holder device) are consistent and repeatable.

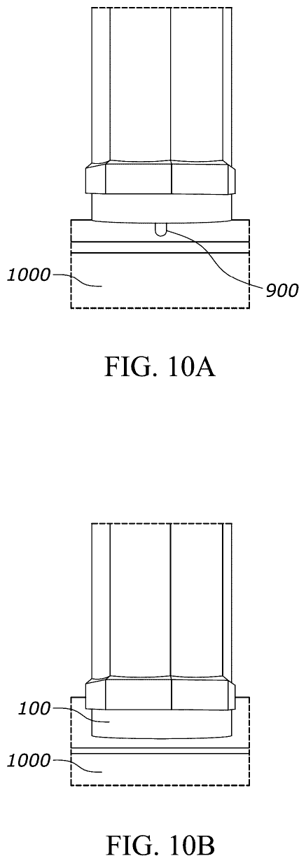

FIG. 10A is a sectional view that depicts an initial position of the tip of the probe 900 upon contact with a surface 1000 that is to be tested in accordance with an illustrative embodiment. FIG. 10B is a sectional view that depicts a test position of the device in which both the distal end of the outer tube and the tip of the probe 900 are in contact with the surface 1000 to be tested in accordance with an illustrative embodiment. While the surface 1000 depicted is wood, it is to be understood that the proposed device can be used to test the integrity of other surfaces as well, such as steel, aluminum, concrete, etc.

As discussed, a major purpose of the proposed probe holder device is to ensure that the pressure holding the sensor/probe to a surface is constant and repeatable. During use of the probe, mechanical energy from the probe passes into the object that is being inspected. In an illustrative embodiment, the probe can be an ultrasonic sensor that has a transmitter which transmits ultrasonic pulses into the material being tested. The ultrasonic sensor also includes a receiver that receives reflections of the transmitted ultrasonic pulses. A processor of the ultrasonic sensor (or a remote device) analyzes the energy loss of the reflections and compares the energy loss to an expected energy loss (i.e., of a material in good condition) to identify decay, delamination, poor bonding, etc. in the materials. Any type of ultrasonic probe/sensor known in the art may be used with the proposed probe holder device.

If the pressure between the probe tip and the material being tested is too low, little energy will pass from the sensor into the inspected object and the probe will be unable to generate usable data. If the pressure is inconsistent, then the obtained data will have an error component that could potentially cause the data to be unusable. In an ideal situation, the sensor is placed securely against the surface of the inspected object at a constant force, and the probe holder device described herein was designed to satisfy this condition. Specifically, the spring compression provided by the probe holder device provides a repeatable, predictable force. As discussed, the probe holder device holds the springs in place and guides compression using mounting posts. The posts also limit the spring compression to prevent excessive forces being transferred to the sensor and inspected object.

In an illustrative embodiment, a tip of the sensor extends beyond the distal end of the outer tube 100 by a fixed distance, as shown in FIG. 10A. The sensor is placed against the inspection surface and the user of the device pushes down on the outer tube. The applied force of the probe tip in contact with the surface can be 5-10 pounds of pressure in one embodiment. Alternatively, the pressure may be less than 5 pounds, 15 pounds, 20 pounds, etc. The springs compress until the end of the outer tube contacts the inspection surface, preventing further compression. The spacer, described with reference to FIGS. 3A and 3B, is used to control the distance by which the tip of the probe/sensor extends beyond the end of the outer tube. Specifically, in one embodiment, different sizes of the spacer can be used to control probe tip position relative to the distal end of the outer tube. The farther the tip of the sensor extends beyond the end of the outer tube, the greater the force necessary to compress the springs. The force necessary to compress the springs is the force that holds the sensor in place and against the inspection surface. A longer spacer increases the contact force and a shorter spacer decreases the contact force. It is up to the user to know the safe level of application force to prevent damage to the sensor and the inspected object. The sensor is prevented from falling out of the out tube by the compression stop described herein.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A probe holder device comprising:
an outer tube, wherein the outer tube includes a distal end and a proximal end, wherein the proximal end is at least partially covered by a cover;
a carriage that includes an upper carriage, a lower carriage, and one or springs that extend between the upper carriage and the lower carriage; and
a compression stop that mounts to the distal end of the outer tube, wherein the compression stop includes an opening.

2. The device of claim 1, wherein the opening in the compression stop is sized to receive at least a portion of a probe mounted within the outer tube such that at least the portion of the probe extends past the distal end of the outer tube.

3. The device of claim 1, wherein the compression stop includes a plurality of posts that extend into the outer tube, wherein the plurality of posts are spaced apart to support at least a portion of a probe that is mounted within the outer tube.

4. The device of claim 1, wherein the cover of the proximal end of the outer tube includes an opening that is sized to receive an electrical cord of a probe that is mounted within the outer tube.

5. The device of claim 1, wherein the upper carriage includes a first base with a first plurality of posts extending therefrom, wherein the one or springs comprise a plurality of springs such that each spring is partially received by a post in the first plurality of posts, and wherein each post in the first plurality of posts has a different length.

6. The device of claim 5, wherein the lower carriage includes a second base with a second plurality of posts extending therefrom, wherein each spring is partially received by a post in the second plurality of posts, and wherein each post in the second plurality of posts has a different length.

7. The device of claim 6, wherein a first spring in the plurality of springs mounts to a first set of posts that includes a first post from the first plurality of posts and a first post from the second plurality of posts, and wherein, in an uncompressed state, the mounted first spring causes a first gap to be formed between the first set of posts.

8. The device of claim 7, wherein a second spring in the plurality of springs mounts to a second set of posts that includes a second post from the first plurality of posts and a second post from the second plurality of posts, and wherein, in an uncompressed state, the mounted second spring causes a second gap to be formed between the second set of posts, wherein the first gap begins at a first distance from a distal end of the lower carriage and the second gap begins at a second distance from the distal end of the lower carriage, and wherein the first distance differs from the second distance
9. The device of claim 1, further comprising a spacer that mounts within the outer tube such that a proximal end of the spacer is in contact with the cover of the outer tube.

10. The device of claim 9, wherein a length of the spacer controls a distance by which a probe extends from the distal end of the outer tube.

11. The device of claim 9, wherein an interior of the spacer includes a truncated cone shape that is sized to at least partially mate with a proximal end of the upper carriage.

12. The device of claim 1, wherein an interior surface of a distal end of the lower carriage is sized to at least partially mate with a proximal end of a probe that is mounted within the outer tube.

13. The device of claim 1, wherein the upper carriage and the lower carriage each include an opening that is sized to receive an electrical cord of a probe that is mounted within the outer tube.

14. The device of claim 1, further comprising one or more collars mounted to an exterior surface of the outer tube, wherein the one or more collars are shaped to prevent movement of the outer tube when the outer tube is placed onto a surface.
